(19) United States
(12) Patent Application Publication
(10) Pub. No.: US 2013/0007568 A1
(43) Pub. Date: Jan. 3, 2013

(54) ERROR CORRECTING CODE DECODING DEVICE, ERROR CORRECTING CODE DECODING METHOD AND ERROR CORRECTING CODE DECODING PROGRAM

(75) Inventor: Toshihiko Okamura, Tokyo (JP)

(73) Assignee: NEC CORPORATION, Tokyo (JP)

(21) Appl. No.: 13/583,186

(22) PCT Filed: Mar. 7, 2011
(86) PCT No.: PCT/JP2011/055224

§ 371 Date: Sep. 6, 2012

(30) Foreign Application Priority Data
Mar. 8, 2010 (JP) 2010-050246

(51) Int. Cl. H03M 13/23; G06F 11/10

(52) U.S. Cl. 714/786; 714/E11.032

(57) ABSTRACT

Provided is an error correction code decoding apparatus capable of performing a decoding process efficiently for various interleaver sizes while suppressing an increase in apparatus size. The error correction code decoding apparatus includes: a simultaneous decoding selection unit configured to select whether a first and a second elementary codes are to be subjected to simultaneous decoding depending on a size of an interleaver; a reception information storage unit configured to store reception information at a position in accordance with a selection result from the simultaneous decoding selection unit; an external information storage unit configured to store external information corresponding to each of the first and the second elementary codes at a position in accordance with the selection result from the simultaneous decoding selection unit; and a soft-input soft output decoding unit including a plurality of soft-input soft-output decoders that perform soft-input soft-output decoding on each of divided blocks of the first and the second elementary codes in parallel, the soft-input soft output decoding unit configured to repeat decoding of the first elementary code and the second elementary code when simultaneous decoding is not selected by the simultaneous decoding selection unit, and configured to repeat simultaneous decoding of the first and the second elementary codes when simultaneous decoding is selected by the simultaneous decoding selection unit.

### TECHNICAL FIELD

The present invention relates to an error correction code decoding device or apparatus, particularly to an error correction code decoding apparatus, an error correction code decoding method, and an error correction code decoding program for decoding a parallel concatenated code represented by a turbo code.

### BACKGROUND ART

An error correction coding technology is a technology for protecting data from an error such as bit inversion occurring on a communicate path during data transmission through data coding and decoding operations. Such an error correction coding technology is widely utilized in various fields, such as wireless communications and digital storage media. Coding is a process of converting information for transmission into a codeword to which redundancy bits are attached.

Decoding is a process of inferring the original codeword (information) from an error-containing codeword (reception word) by utilizing the redundancy.

A turbo code proposed by Berrou et al. has been finding increasing practical use for mobile applications due to its high correcting capability. The turbo code is discussed in Non-patent Literature 1.

FIG. 1 shows a configuration of a turbo coder 100 and a turbo code decoder 110.

The turbo coder 100 shown in FIG. 1(a) includes two systematic feedback convolutional coders 101 and 102 concatenated in parallel via an interleaver 103. This convolutional code is referred to as an elementary code of a turbo code, for which normally a code with the number of memories of not more than 4 is used. FIG. 1 shows an example where the number of memories is two. In the following, the coder 101 will be referred to as an “elementary code 1”, and the coder 102 will be referred to as an “elementary code 2”, and a parity series generated by each will be referred to as a “parity 1” and a “parity 2”, respectively. The interleaver 103 performs a bit rearranging process. Coding performance is greatly affected by the size and design of the interleaver 103.

A configuration of the turbo code decoder 110 shown in FIG. 1(b) will be described. A soft-input soft-output (which may be hereafter referred to as “SISO”) decoder 111 performs a decoding process corresponding to each elementary code. Memories 112, 113, and 114 retain reception values corresponding to an information series, the parity 1, and the parity 2, respectively. A memory 115 retains a soft output value (external information) obtained by SISO decoding of the elementary codes. A de-interleaver 116 performs a process of arranging back the rearrangement made by the interleaver 103. A feature of the turbo code decoding method is that a soft output value (external information) obtained by SISO decoding of an elementary code is utilized as a soft input value (a priori information) of another elementary code repeatedly. In the following, the description is based on the assumption that the elementary codes of the turbo code are binary convolutional codes.

An optimum soft output decoding involves determining “0” or “1” by calculating the a posteriori probability of each information bit on the basis of the reception series under a constraint condition of the codeword. For this purpose, calculation of the following expression (1) is sufficient.

L(t)=log(P(u(t)=0|Y)/P(u(t)=|Y)) (1)

where u(t) is an information bit at a point in time t, Y is a series of reception values for the codeword, and P(u(t)=b|Y)(b=0, 1) is the conditional probability such that u(t)=b is established under the reception series Y. It is very difficult to determine L(t) by a conventional error correction code in terms of calculation amount. However, in the case of a convolutional code with a small number of memories, such as an elementary code of a turbo code, the entire codeword can be expressed by a code trellis with a small number of states, use of which enables efficient SISO decoding. This algorithm, which may be referred to as BCJR algorithm or MAP algorithm, is described in Non-patent Literature 2.

The MAP algorithm can be applied to SISO decoding used in the turbo code. A soft output value exchanged during the repetition of decoding of the turbo code is not the value L(t) per se of the expression (1), but a value Le(t) referred to as external information calculated from L(t) and expressed by the following expression (2).

Le(t)=L(t)−C·x(t)−La(t) (2)

where x(t) is a reception value for the information bit u(t), La(t) is external information obtained by soft output decoding of the other elementary code used as the priori information of u(t), and C is a coefficient determined by the SN ratio (signal to noise ratio) of the communication path.

The MAP algorithm will be described in detail. In a convolutional code, the codeword for input information varies depending on the memory value in the coder. The memory value in the coder is referred to as a “state” of the coder. Coding by the convolutional code involves producing an output while the state is varied depending on the information series. The code trellis is a representation of combinations of transition of the state in a graph. In the code trellis, the state of the coder at each point in time is expressed as a node, and an edge is assigned to a pair of nodes in a state in which transition from each node exists. To the edge, a label of the codeword that is output in the transition is assigned. Links of the edges are referred to as paths, and the label of a path corresponds to a codeword series of the convolutional code.

FIG. 2(a) shows a configuration of a convolutional coder (number of memories 2) for the elementary codes shown in FIG. 1. FIG. 2(b) shows a code trellis corresponding to the coder of FIG. 2(a). In the initial state, the memories are all zero. The state of the coder corresponds to the values of the memories. In the convolutional code of FIG. 2, when the initial information bit is 0, the codeword “00” is output such that the state is “00” at a point in time 1. When the information bit is 1, the codeword “11” is output and the state at the point in time 1 is “10”. At a point in time 2, a codeword corresponding to the information bit 0 or 1 is output and state transition to the point in time 2 occurs for each of the states “00” and “11” at the point in time 1. The state of the coder may be expressed by an integer of the bit number corresponding to the number of memories, such as 0 for “00” and 3 for “11”.

Similar to the Viterbi algorithm which is a well-known decoding algorithm utilizing the code trellis, the MAP algorithm is based on a process of successively calculating the correlation (path metric) between the code trellis paths and the reception value series. The MAP algorithm may largely consist of the following three types of processes.
(a) Forward process: Calculates the path metric reaching from the head of the code trellis to each node.
(b) Backward process: Calculates the path metric reaching from the terminus of the code trellis to each node.
(c) Soft output generation process: Calculates the soft output (a posteriori probability ratio) of an information symbol at each point in time by using the results of (a) and (b).

The path metric in the forward process relatively indicates the probability (or its logarithmic value) of reaching from the head of the code trellis to each node under the reception series and the a priori information. The path metric in the backward process relatively indicates the probability (or its logarithmic value) of reaching from the end of the code trellis to each node. Assume that S denotes a set of states of a convolutional code, and that α(t, s) and β(t, s) denote the path metric calculated by the forward process and the backward process, respectively, at a node in state s (∈ S) at a point in time t. Further, assume that γ(t, s, s′) denotes a branch metric which is the likelihood determined by the information bit and the codeword during transition from state s to state s′ at the point in time t, and the reception value and the priori information (or the soft output of the other elementary code in the case of turbo code). In an additive white Gaussian communication path, γ(t, s, s′) can be easily calculated by using the Euclidean distance between a modulated value of the codeword output by transition from state s to state s′ and the reception value, and the a priori information for the information bit. In this case, the forward process and the backward process are performed as follows by using the values one point in time previously or later (the path metric and the soft output are expressed in the log domain):
(a) Forward process:

α(t, s)=log(Σ_{s′∈S:τ(s′, b)=s, b=0,1}exp(α(t−1, s′)+γ(t−1, s′, s))) (3)
(b) Backward process:

β(t, s)=log(Σ_{s′∈S:τ(s , b)=s′, b=0,1}exp(β(t+1, s′)+γ(t, s, s′))) (4)
(c) Soft output generation process:

L(t)=log(Σ_{—}{s, s′∈S:τ(s, 0)=s′}exp(α(t, s)+γ(t, s, s′)+β(t+1, s′)))−log(Σ_{—}{s, s′∈S:τ(s, 1)=s′}exp(α(t, s)+γ(t, s, s′)+β(t+1, s))) (5)

where τ(s′, b)=s indicates the transition from state s′ to state s with information bit b, and Σ_{s′∈S:τ(s′, b)=s, b=0, 1} indicates taking a sum regarding all of states s that become state s′ at the next point in time. Σ_{s, s′∈S:τ(s, b)=s′} indicates taking a sum regarding a pair of states {s, s′} of which the information bit during state transition from state s to state s′ becomes b.

A Max-Log-MAP algorithm is performed by varying the sum by the maximum value in the processes of expressions (3), (4), and (5). Because the need for conversion to exp and log is eliminated, the algorithm can be realized with the same process as the ACS (Add-Compare-Select) process in the Viterbi algorithm, thus enabling significant simplification.

In order to generate the soft output according to expression (5), it is necessary for a of the forward process and β of the backward process to be aligned with each other at each point in time t, and it is also necessary to determine the scheduling as to in what order the generation of α and β should be performed at each point in time. In a simple method, as shown in FIG. 3(a), a schedule may be determined whereby β is generated at each point in time by performing the backward process from the terminus of the code trellis, and then the forward process and the soft output generation process are performed from the head of the trellis. In this schedule, a delay corresponding to the trellis length, i.e., the information length, is caused, which imposes a limit on the increase in speed. Further, it is necessary to retain β for the information length, and a large amount of memory needs to be used.

Thus, a scheduling may be devised whereby, by taking advantage of the property that the MAP algorithm for the convolutional code can be performed on the code trellis locally to some extent, the code trellis is divided into windows (size at a point in time W) as shown in FIG. 3(b), and the forward process, the backward process, and the soft output generation process are performed on a window by window basis. In FIG. 3(b), numeral 301 designates the timing of a training process of the backward process, and β for the point in time W is updated according to expression (4). For the initial value, the same value of β may be set for all of the states, or, in the case of turbo code decoding, a value calculated by the previous process in iterative decoding may be used. Numeral 302 indicates the timing of the forward process, in which the path metric α according to expression (3) is retained until the soft output generation process at that point in time is completed. Numeral 303 indicates the timing for performing the backward process by using the path metric at the window boundary calculated in 301 as the initial value and simultaneously generating the soft output by utilizing the α of 302. In FIG. 3, a scheduling may be adopted such that the forward process and the backward process are exchanged.

Because the SISO decoding using the window is capable of localized processing, naturally it may occur to attempt an increase in speed by providing a plurality of localized SISO decoders and implementing them in parallel. FIG. 4 schematically shows an example of a decoding process in which the code trellis is divided into four blocks and four SISO decoders (SISO0-SISO3) are used.

The backward process corresponding to a code trellis termination process may be calculated in advance, so that the division may be considered by excluding the termination portion even though termination of the code trellis is being performed. At this time, the number of points in time of the code trellis agrees with an information length (=interleaver length) K. When the code trellis is divided into M portions and M SISO decoders are used for the decoding process, the number of points in time of processing per decoder (=size of block) is B=K/M points in time. In the window process in FIG. 3, a delay of 2 W points in time is caused in the backward process training. However, if the block is sufficiently large compared to the window, nearly M-fold increase in speed can be achieved in the decoding process using the M SISO decoders.

When parallelization by a plurality of SISO decoders is considered, it is desirable to make a configuration in which the information reception value memory, the external information memory, and the parity reception value memory are also divided, and to prevent simultaneous access to the same memory from the plurality of SISO decoders. When a memory access contention (memory contention) due to the plurality of SISO decoders develops, as illustrated in FIG. 5, it is necessary to perform a process for maintaining high speed by avoiding the contention by subdividing the memory or increasing the number of ports, or for permitting the delay by providing a buffer. The former may lead to a significant increase in apparatus size, and the latter may lead to a significant decrease in decoder throughput. As regards the parity reception value, memory access contention can be avoided and access can be made with the same address by retaining the parity reception value divided by the number of blocks so as to correspond to the blocks divided by the elementary code 1 and the elementary code 2. Thus, the parity reception value memory can be realized with a single memory. However, as regards the information reception value and the external information, the same memory would be accessed at the time of decoding the elementary code 1 and the elementary code 2. Namely, even when the memory is prepared for the blocks corresponding to the elementary code 1, access during the decoding of the elementary code 2 would use the interleaved address. Thus, a simple random interleaver would normally generate memory access contention. Similarly, when a radix-2̂n algorithm is considered for parallelization involving the processing for n points in time of the code trellis in one cycle of the MAP algorithm, memory access contention may develop even when the memory for external information and the like is divided into n portions.

To address this problem, a method is known whereby the interleaver is designed such that memory access contention can be prevented. Assume the use of M SISO decoders for performing the MAP algorithm for radix-2̂n. The interleaver adopted by the 3GPP LTE (3rd Generation Partnership Project Long Term Evolution) guarantees no memory access contention at the time of parallel decoding by M radix-2̂n SISO decoders when the interleaver size K is a multiple of M·n. This is because, when the interleaver size K is a multiple of M·n, the interleaver retains the information reception value and the external information divided in memories corresponding to the M·n blocks. The interleaver for the 3GPP LTE is discussed in Non-patent Literature 3, for example.

For mobile applications where the information length is often small, a system may be adopted whereby the communication efficiency is increased by making the interleaver size K of the turbo code finely adaptable. For the turbo code for 3GPP LTE in Non-patent Literature 3, the interleaver is set for 188 among K=40 to 6144. The smaller the K, the finer are the steps at which the interleaver is set. For example, the interleaver is set for each of the sizes of 8 steps for K=40 to 512, 16 steps for K=512 to 1024, 32 steps for K=1024 to 2048, and 64 steps for K=2048 or more. In this case, in order to handle all of the interleaver sizes, the limit of the degree of parallelism is M·n=8.

As a parallelization technique for turbo code decoding, a method is known whereby two elementary codes are simultaneously decoded. This technique is discussed in Patent Literature 1.

FIG. 6 shows a configuration of a decoding apparatus described in Patent Literature 1. In FIG. 6, the code trellis for the elementary code 1 and the elementary code 2 is each partitioned into 4 blocks, for which SISO decoders (SISO0-SISO7) perform a decoding process simultaneously. A substitution process unit 601 and a substitution process unit 602 each perform a substitution process for realizing the assigning of external information between the memory and the SISO decoders, and its inverse transform process, corresponding to the interleaver. The substitution process unit 601, in decoding the elementary code 2, performs the same substitution process for the information reception value (not shown) and assigns an input to the SISO decoders. The decoding apparatus described in Patent Literature 1 is characterized in that SISO decoding is performed by utilizing the external information generated by the other elementary code immediately as a priori information. Thus, when the block length B=K/M is large compared to W, the converging speed of iterative decoding can be also increased. However, in this parallelization technique, the external information, the information reception value and the like need to be stored in different memories depending on the elementary code, as shown in FIG. 6, so that the memory size becomes twice as large as that of the system illustrated in FIG. 1.

### CITATION LIST

### Non-patent Literature

{NPTL 1} C. Berrou et al., “Near Shannon limit error-correcting coding and decoding: Turbo codes”, Proc. IEEE International Conference of Communications (ICC), pp. 1064-1070, 1993.

{NPTL 2} L. R. Bhal et al., “Optimal decoding of linear codes for minimizing symbol error rate”, IEEE Transaction on Information Theory, pp. 284-287, 1974.

{NPTL 3} 3rd Generation Partnership Project: Technical Specification Group Radio Access Network; Evolved Universal Terrestrial Radio Access (E-UTRA), Multiplexing and channel coding (Release 8), 2009.

### Patent Literature

{PTL 1} JPA2007-006541

### SUMMARY OF INVENTION

### Technical Problem

However, in the 3GPP LTE decoding apparatus described in Non-patent Literature 3, the degree of parallelism is limited, so that a decoding process is not efficiently performed for various interleaver sizes of the turbo code used in mobile applications.

Further, in the decoding apparatus described in Patent Literature 1, an increase in memory size is required for an efficient decoding process, resulting in an increase in apparatus size.

The present invention has been made in order to solve the above problems, and an object of the present invention is to provide an error correction code decoding apparatus capable of efficiently performing a decoding process for various interleaver sizes while preventing an increase in apparatus size.

### Solution to Problem

According to the present invention, there is provided an error correction code decoding apparatus for repeatedly decoding reception information of coding information including a first elementary code which is an information convolutional code, a second elementary code which is a convolutional code of the information substituted by an interleaver, and the information, the error correction code decoding apparatus including:
a simultaneous decoding selection means configured to select whether the first and the second elementary codes are to be subjected to simultaneous decoding depending on a size of the interleaver,
a reception information storage means configured to store the reception information at a position in accordance with a selection result from the simultaneous decoding selection means;
an external information storage means configured to store external information corresponding to each of the first and the second elementary codes at a position in accordance with the selection result from the simultaneous decoding selection means; and
a soft-input soft output decoding means including a plurality of soft-input soft-output decoders configured to perform soft-input soft-output decoding on each of divided blocks of the first and the second elementary codes in parallel on the basis of the reception information and the external information and each configured to output the external information, the soft-input soft output decoding means configured to repeat decoding of the first elementary code and the second elementary code successively when the simultaneous decoding is not selected by the simultaneous decoding selection means, and configured to repeat simultaneous decoding of the first and the second elementary codes when the simultaneous decoding is selected by the simultaneous decoding selection means.

According to the present invention, there is provided an error correction code decoding method including, by using an error correction code decoding apparatus for repeatedly decoding reception information of coding information including a first elementary code which is an information convolutional code, a second elementary code which is a convolutional code of the information substituted by an interleaver, and the information:
selecting whether the first and the second elementary codes are to be subjected to simultaneous decoding depending on a size of the interleaver;
storing the reception information in a reception information storage means at a position in accordance with a result of the selecting of simultaneous decoding;
storing external information corresponding to each of the first and the second elementary codes in an external information storage means at a position in accordance with the result of the selecting of simultaneous decoding;
repeating, by using a plurality of soft-input soft-output decoders configured to perform soft-input soft-output decoding on each of divided blocks of the first and the second elementary codes in parallel on the basis of the reception information and the external information, and each configured to output the external information, successive decoding of the first elementary code and the second elementary code when the simultaneous decoding is not selected, or simultaneous decoding of the first and the second elementary codes when the simultaneous decoding is selected.

An error correction code decoding program according to the present invention is configured to cause an error correction code decoding apparatus for repeatedly decoding reception information of coding information including a first elementary code which is an information convolutional code, a second elementary code which is a convolutional code of the information substituted by an interleaver, and the information to perform: a simultaneous decoding selection step of selecting whether the first and the second elementary codes are to be subjected to simultaneous decoding in accordance with a size of the interleaver; a reception information storing step of storing the reception information in a reception information storage means at a position in accordance with a result of the selecting of simultaneous decoding; an external information storing step of storing external information corresponding to each of the first and the second elementary codes in an external information storage means at a position in accordance with the result of the selecting of simultaneous decoding; and a soft-input soft-output decoding step of, by using a plurality of soft-input soft-output decoders configured to perform soft-input soft-output decoding on each of divided blocks of the first and the second elementary codes in parallel on the basis of the reception information and the external information, and each configured to output the external information, repeating decoding of the first elementary code and decoding of the second elementary code successively when the simultaneous decoding is not selected, or repeating simultaneous decoding of the first and the second elementary codes when the simultaneous decoding is selected.

### Advantageous Effects of Invention

The present invention can provide an error correction code decoding apparatus capable of efficiently performing a decoding process for various interleaver sizes while suppressing an increase in apparatus size.

### BRIEF DESCRIPTION OF DRAWINGS

FIG. 1(a) and FIG. 1(b) A configuration diagram in FIG. 1(a) shows a turbo coder according to a related art, and a configuration diagram in FIG. 1(b) shows a turbo code decoder according to the related art.

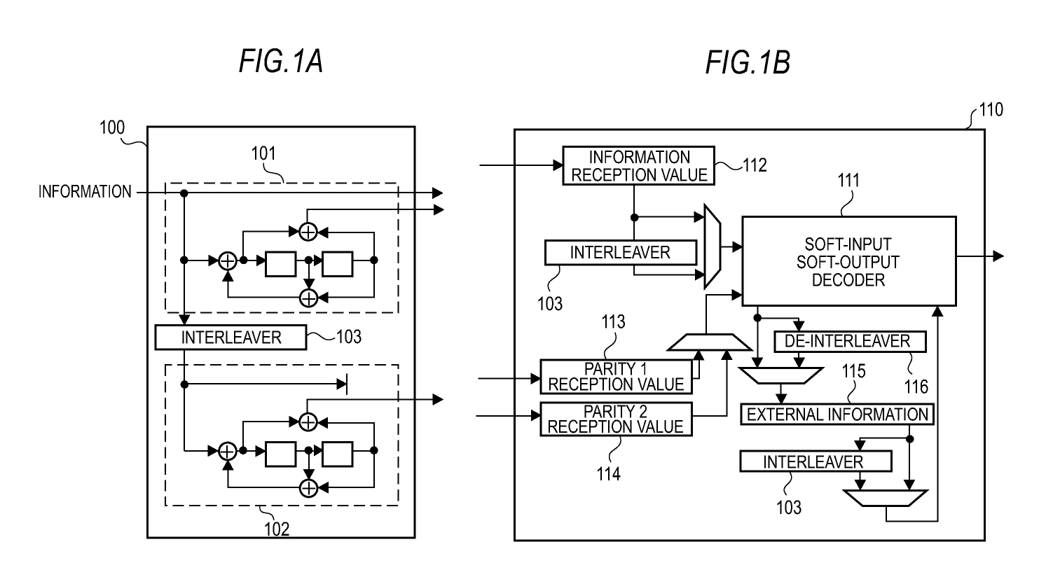

FIG. 2(a) and FIG. 2(b) A configuration diagram in FIG. 2(a) shows a convolutional coder in the turbo code decoder according to the related art, and a conceptual chart in FIG. 2(b) shows a code trellis indicating state transition of the convolutional coder.

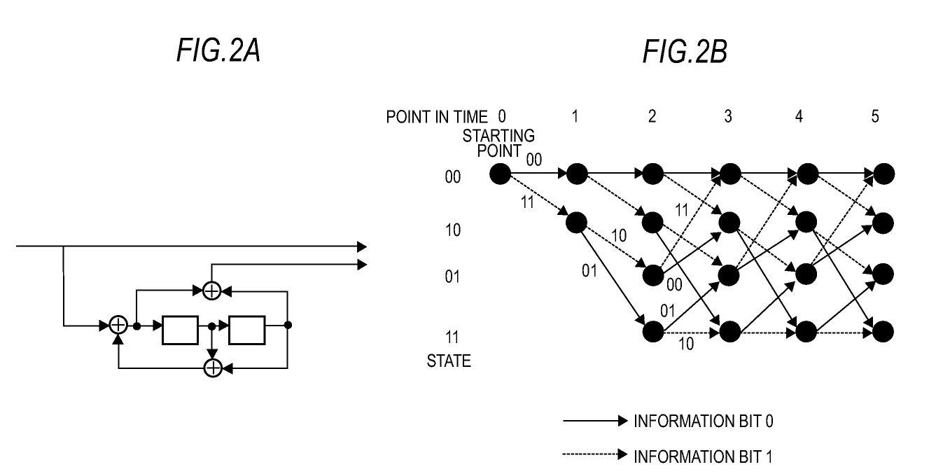

FIG. 3(a) and FIG. 3(b) A diagram in FIG. 3(a) shows a sequence of a forward process, a backward process, and a soft output generation process in an MAP algorithm of the turbo code decoder according to the related art, and a diagram in FIG. 3(b) shows a sequence of the forward process, the backward process, and the soft output generation process using a window according to the MAP algorithm.

FIG. 4 A diagram schematically illustrates parallelization in a turbo code decoding apparatus according to the related art in which a simultaneous SISO decoding is performed in each of divided blocks of the code trellis.

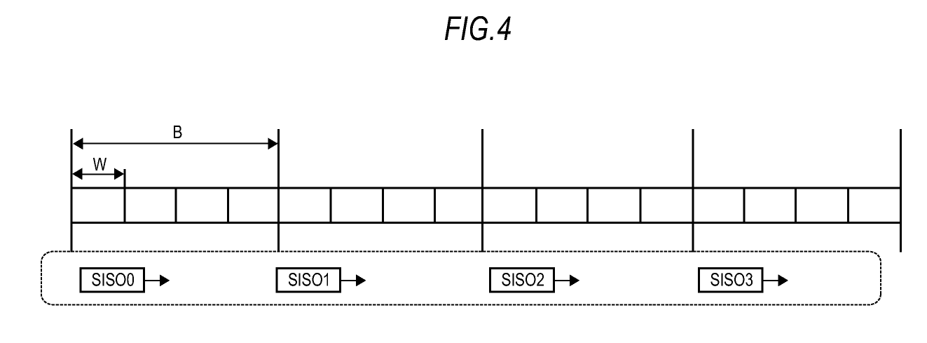

FIG. 5 A diagram schematically illustrates a situation in which memory access contention develops during parallelization of SISO decoding in the turbo code decoding apparatus according to the related art.

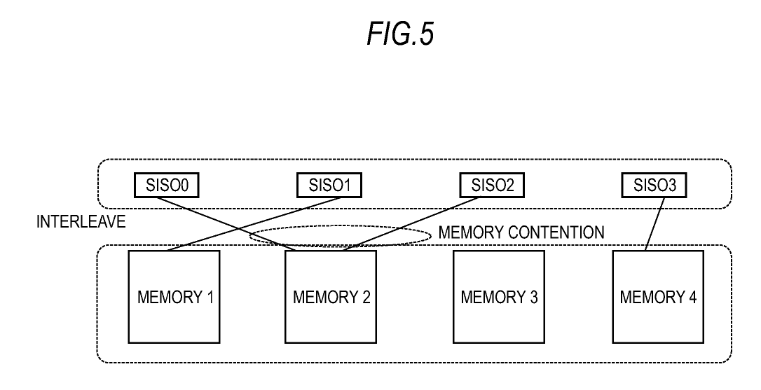

FIG. 6 A configuration diagram shows a turbo code decoding apparatus according to another related art.

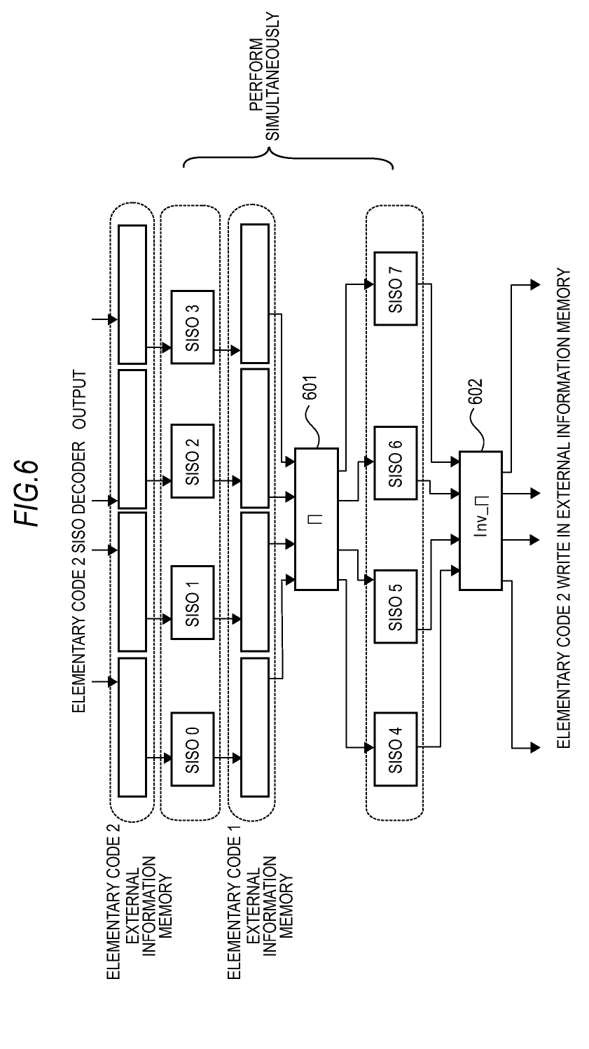

FIG. 7 A configuration diagram shows an error correction code decoding apparatus according to a first embodiment of the present invention.

FIG. 8 A flowchart shows an operation of the error correction code decoding apparatus according to the first embodiment of the present invention.

FIG. 9 A configuration diagram shows a turbo code decoding apparatus according to a second embodiment of the present invention.

FIG. 10 A explanatory diagram illustrates a memory configuration according to the second embodiment of the present invention.

FIG. 11 A block diagram shows a configuration of a substitution unit according to the second embodiment of the present invention.

FIG. 12 A block diagram shows an arrangement of a hard decision unit according to the second embodiment of the present invention.

FIG. 13 A block diagram shows a configuration of the hard decision unit according to the second embodiment of the present invention.

FIG. 14 A graph illustrates the characteristics of the turbo code decoding apparatus according to the second embodiment of the present invention as applied for the decoding of a 3GPP LTE turbo code (interleaver length 504).

### DESCRIPTION OF EMBODIMENTS

In the following, a first embodiment of the present invention will be described in detail with reference to the drawings.

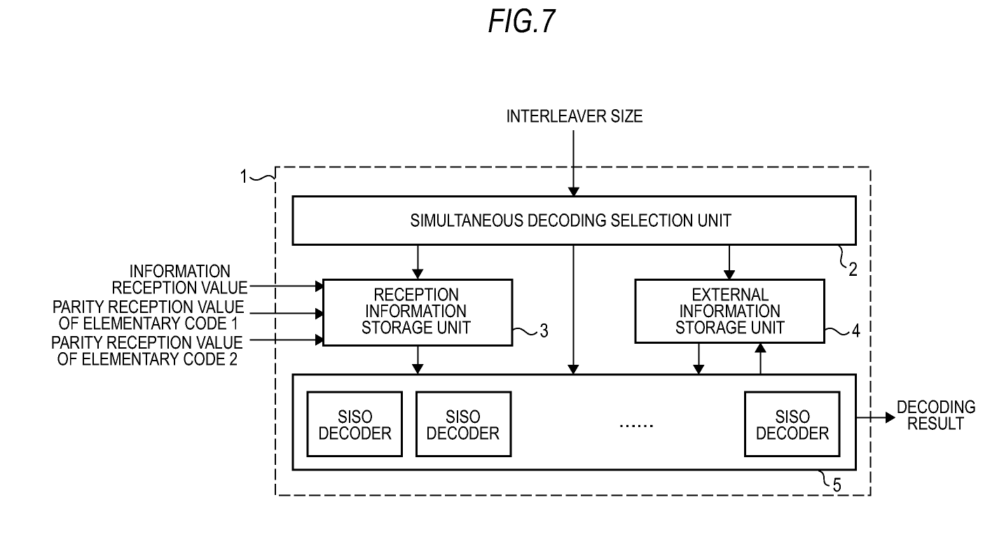

FIG. 7 shows a configuration of an error correction code decoding apparatus 1 according to the first embodiment of the present invention. In FIG. 7, the error correction code decoding apparatus 1 includes, as functional blocks, a simultaneous decoding selection unit 2, a reception information storage unit 3, an external information storage unit 4, and a soft-input soft-output decoding unit 5.

The simultaneous decoding selection unit 2 includes a circuit for realizing a simultaneous decoding selection function as will be described later. The reception information storage unit 3 and the external information storage unit 4 include a storage apparatus such as a RAM (Random Access Memory) and a control circuit for controlling the reading and writing of data in the storage apparatus. The soft-input soft-output decoding unit 5 includes M (M is an integer of one or more) SISO decoders.

The simultaneous decoding selection unit 2 determines an interleaver size K on the transmission side and the reception side at the start of a communication session. The simultaneous decoding selection unit 2 also outputs a selection result (determination information) for selecting or determining whether an elementary code 1 and an elementary code 2, which will be described later, are to be subjected to simultaneous decoding depending on the determined interleaver size K (K is an integer of one or more).

The reception information storage unit 3 receives, via a communication path from an error correction coder which is not shown, the elementary code 1, which is a convolutional code of information, the elementary code 2, which is a convolutional code of the information substituted by the interleaver, and coding information including the information. The reception information storage unit 3 stores the received reception information.

The reception information includes an information reception value corresponding to the information, a parity 1 reception value corresponding to a parity of the elementary code 1, and a parity 2 reception value corresponding to a parity of the elementary code 2.

The reception information storage unit 3 also stores the reception information at a position in accordance with the selection result from the simultaneous decoding selection unit 2.

The external information storage unit 4 stores external information soft-output by the SISO decoders of the soft-input soft-output decoding unit 5 at a position in accordance with the selection result from the simultaneous decoding selection unit 2.

The soft-input soft-output decoding unit 5 includes M SISO decoders that perform a radix-2̂n MAP algorithm capable of a localized process using a window, for example. In this case, the M SISO decoders constitute an embodiment of L (=M·n) SISO decoders according to the present invention.

When simultaneous decoding is not selected by the simultaneous decoding selection unit 2, the soft-input soft-output decoding unit 5 repeats the successive decoding of the elementary code 1 and the elementary code 2. Specifically, the soft-input soft-output decoding unit 5 successively repeats a process of performing the decoding of each of divided blocks of the code trellis of the elementary code 1 in parallel, and a process of performing the decoding of each of divided blocks of the code trellis of the elementary code 2 in parallel, by using the plurality of SISO decoders.

The soft-input soft-output decoding unit 5, when simultaneous decoding is selected by the simultaneous decoding selection unit 2, repeats the simultaneous decoding of the elementary code 1 and the elementary code 2. Specifically, the soft-input soft-output decoding unit 5 repeats the decoding of the divided blocks of the code trellis of the elementary code 1 and the decoding of the divided blocks of the code trellis of the elementary code 2 simultaneously and in parallel.

In the following, the process of the soft-input soft-output decoding unit 5 repeating the successive decoding of the elementary code 1 and the elementary code 2 will be referred to as a “normal parallelization”. The process of the soft-input soft-output decoding unit 5 simultaneously performing the decoding of the elementary code 1 and the decoding of the elementary code 2 will be referred to as a “simultaneous decoding of elementary codes”.

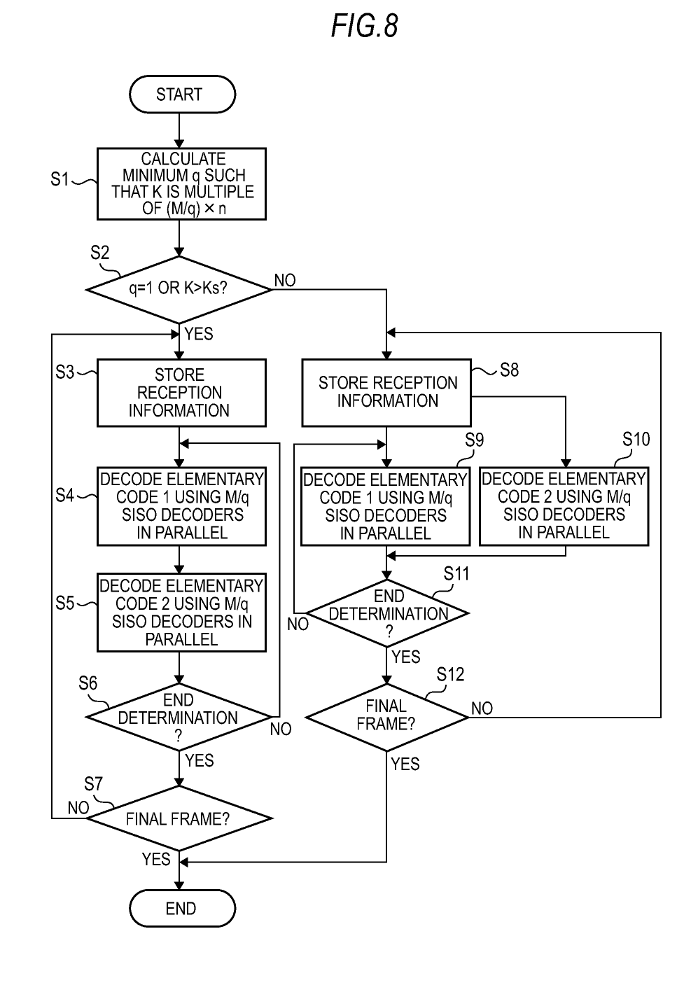

Next, an operation of the error correction code decoding apparatus 1 according to the first embodiment of the present invention will be described with reference to FIG. 8.

In FIG. 8, the error correction code decoding apparatus 1 has stored Ks in advance as the maximum value of interleaver size allowing the simultaneous decoding of the elementary code 1 and the elementary code 2.

In FIG. 8, the error correction code decoding apparatus 1 has already determined the interleaver size K between the transmission side and the reception side at the start of a communication session, and uses the same interleaver size K when a plurality of frames are transmitted in the session.

In FIG. 8, first the error correction code decoding apparatus 1 determines a minimum divisor q of M such that the interleaver size K of the current session becomes a multiple of (M/q)×n (step S1).

Then, the simultaneous decoding selection unit 2 outputs a selection result selecting whether the simultaneous decoding of the two elementary codes is to be performed depending on the interleaver size K (step S2).

The simultaneous decoding selection unit 2, for example, may select whether the simultaneous decoding of the elementary code 1 and the elementary code 2 is to be performed depending on whether q=1 or K>Ks is valid.

In step S2, when q=1 or K>Ks and the normal parallelization is selected, the reception information storage unit 3, on the basis of the selection result, reads the information reception value and the parity reception value into an address corresponding to the normal parallelization (step S3).

Then, the soft-input soft-output decoding unit 5 performs the decoding of the elementary code 1 by using the M/q SISO decoders (step S4), and thereafter decodes the elementary code 2 by using the M/q SISO decoders (step S5).

The soft-input soft-output decoding unit 5 repeats steps S4 to S5 until determination of completion of the repetitive decoding (“Yes” in step S6).

Upon completion of the decoding process for all of the frames of the current session, the error correction code decoding apparatus 1 completes the decoding process for the session (“Yes” in step S7).

On the other hand, when the simultaneous decoding of the two elementary codes is selected in step S2, the reception information storage unit 3, on the basis of the selection result, reads the information reception value and the parity reception value into an address corresponding to the simultaneous decoding of the elementary codes (step S8).

Then, the soft-input soft-output decoding unit 5 simultaneously performs the decoding of the elementary code 1 by using the M/q SISO decoders and the decoding of the elementary code 2 by using other M/q SISO decoders (steps S9 and S10).

The soft-input soft-output decoding unit 5 repeats the simultaneous performance of steps S9 and S10 until determination of completion of the repetitive decoding (“Yes” in step S11).

Upon completion of the decoding process for all of the frames in the current session, the error correction code decoding apparatus 1 completes the decoding process for the session (“Yes” in step S12).

Thus, the error correction code decoding apparatus 1 completes its operation.

In steps S1 and S2, the simultaneous decoding selection unit 2 may perform the process of steps Si and S2 for all interleaver sizes K and store the result in a storage apparatus (not shown) in advance, and later refer to the stored result during performance. Preferably, the simultaneous decoding selection unit 2 may make the selection as to whether the simultaneous decoding is to be performed or not simply on the basis of the determination of whether K>Ks is established. In this case, when K is small, the block size B is necessarily small, resulting in greater overhead for the backward process training for the window size W. Therefore, it can be expected that performing the simultaneous decoding of the two elementary codes while decreasing the degree of parallelism per elementary code can contribute to faster speed.

In steps S5 and S11, the soft-input soft-output decoding unit 5 may make the completion determination by using a CRC attached to the information portion in advance.

Next, the effect of the first embodiment of the present invention will be described.

The error correction code decoding apparatus according to the first embodiment of the present invention can efficiently perform the decoding process for various interleaver sizes while suppressing an increase in apparatus size.

This is because the error correction code decoding apparatus selectively employs, in combination, the normal parallelization, in which the decoding of individual blocks is performed in parallel for each elementary code and in which the decoding of the elementary code 1 and the decoding of the elementary code 2 are successively repeated, and the parallelization in which the decoding of the two elementary codes is performed simultaneously.

Further, the error correction code decoding apparatus according to the first embodiment of the present invention stores the reception information and the external information in the reception information storage unit and the external information storage unit at a position in accordance with the selection result regarding whether the simultaneous decoding is to be performed or not. Thus, an increase in the capacity of the reception information storage unit and the external information store can be suppressed.

Next, a second embodiment of the present invention will be described with reference to the drawings. According to the second embodiment of the present invention, an example will be described in which an error correction code decoding apparatus according to the present invention is applied to a turbo code decoding apparatus for decoding a turbo code.

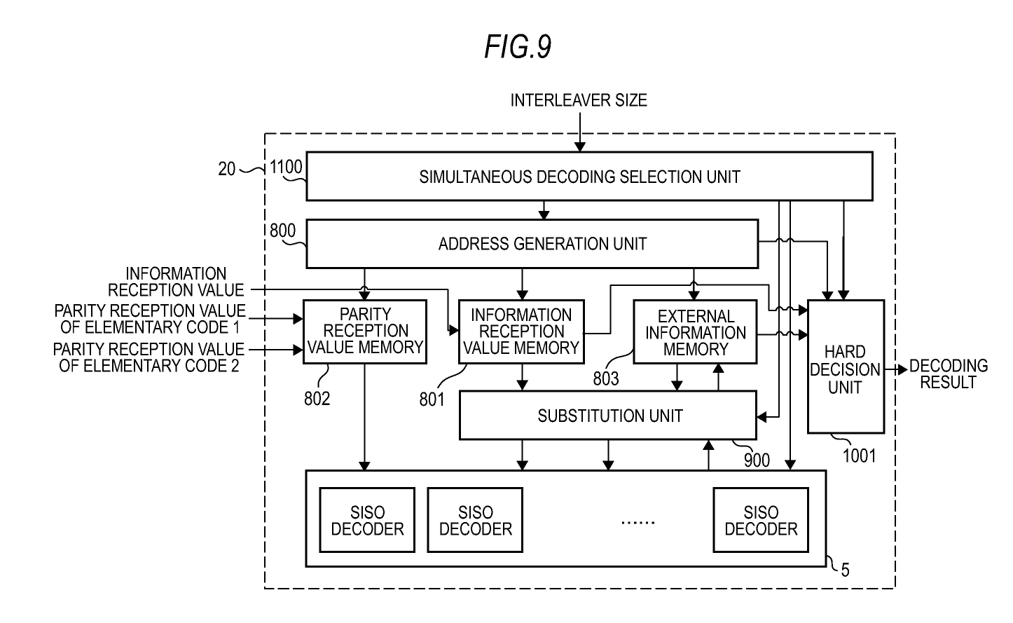

FIG. 9 shows a configuration of a turbo code decoding apparatus 20 according to the second embodiment of the present invention. In FIG. 9, portions similar to those of the error correction code decoding apparatus 1 according to the first embodiment of the present invention will be designated with similar reference signs and their detailed description will be omitted.

In FIG. 9, the turbo code decoding apparatus 20 includes a simultaneous decoding selection unit 1100, an address generation unit 800, an information reception value memory 801, a parity reception value memory 802, an external information memory 803, a soft-input soft-output decoding unit 5, a substitution unit 900, and a hard decision unit 1001.

The address generation means 800, the information reception value memory 801, and the parity reception value memory 802 constitute an embodiment of a reception information storage means according to the present invention. The address generation means and the external information memory 803 constitute an embodiment of an external information storage means according to the present invention.

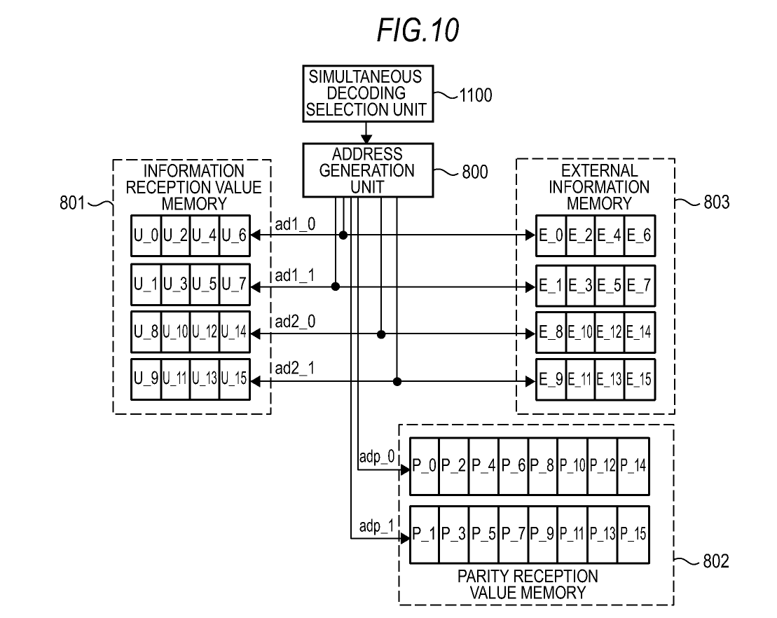

FIG. 10 shows a configuration of the address generation means 800, the information reception value memory 801, the parity reception value memory 802, and the external information memory 803 where M=8 and n=2 are established.

The address generation unit 800 generates, in accordance with the selection result from the simultaneous decoding selection unit 1100, addresses for reading/writing of the information reception value memory 801, the parity reception value memory 802, and the external information memory 803. A method of generating the address will be described later.

The information reception value memory 801 includes (M·n) memories U_0, U_1, U_{M·n−1}. The information reception value memory 801 retains K information reception values divided by M′ =M/q into equal blocks which are further divided by mod n of the address in (M′·n) memories. Namely, when the information reception value memory is represented by U_0, U_1, U_{M′·n−1} and the information reception value by x(j)(j=0, . . . , K−1), B/n reception values of x(j·B+i), x(j·B+i+n), x(j·B+i+2n), . . . , x(j·B+i+B−n) are stored in the memory U_{n·j+1)(0≦i<n), where B=K/M′ is the block size. When the simultaneous decoding of elementary codes is performed, q>1, and the same data as in the memory U_{n·j+i} is stored in the memory U_{2(n·j +i)}. The memories U_0, U_1, . . . , U_{M′·n−1} are used for the decoding of the elementary code 1. The memories U_{M′·n}, U_{M′·n+1}, . . . , U_{2·M′·n−1 } are used for the decoding of the elementary code 2.

The parity reception value memory 802 includes (M·n) memories. In the case of the normal parallelization, the reception values of the parity 1 and the parity 2 divided into M′=M/q equal portions are retained in M′ memories. When the reception values of the parity 1 and the parity 2 are represented by y1(j) and y2(j)(j=0, 1, . . . , K−1), the memory P_{n·j+i}(0≦i<n) stores 2·B/n reception values of y1(j·B+1), y1(j·B+i+n), . . . , y1(j·B+i+B−n), y2(j·B+i), y2(j·B+i+n), and y2(j·B+i+B−n). In the case of the simultaneous decoding of elementary codes, each of the K reception values of the parity 1 and the parity 2 is divided into M′=M/q equal portions (q>1), and the memories P_0 , P_1, , and P_{M′·n−1} retain the reception value of the parity 1 while the memories P_{M′·n}, (P_{M′·n+1}, . . . , and P_{2·M′·n−1} retain the reception value of the parity 2.

The external information memory 803 includes (M·n) memories. In the case of the normal parallelization, the external information memory 803 retains K pieces of external information divided into M′=M/q equal portions in M′ memories, in the same way as the information reception values. The external information herein refers to information soft-output by the SISO decoders of the soft-input soft-output decoding unit 5 and further substituted into a priori information by the substitution unit 900, as will be described later. Specifically, in the case of the simultaneous decoding of elementary codes, the external information memory 803 divides the K pieces of external information into M′ equal portions, and stores the external information e1(j), which is the SISO decoding output of the elementary code 1, in the memories E_{M′·n}, E_{M′·n+1), . . . , E_{2·M′·n−1) such that it becomes the a priori information for the SISO decoding of the elementary code 2. The external information memory 803 stores the external information e2(j), which is the SISO decoding output of the elementary code 2, in the memories E_0, E_1, . . . , and E_{M′·n−1} such that it becomes the a priori information for the SISO decoding of the elementary code 1.

A total of the memory size of the information reception value memory 301 and the external information memory 803 is set to be equal to or more than twice the maximum value Ks of the interleaver size allowing simultaneous decoding, and equal to or more than the maximum value of the interleaver size.

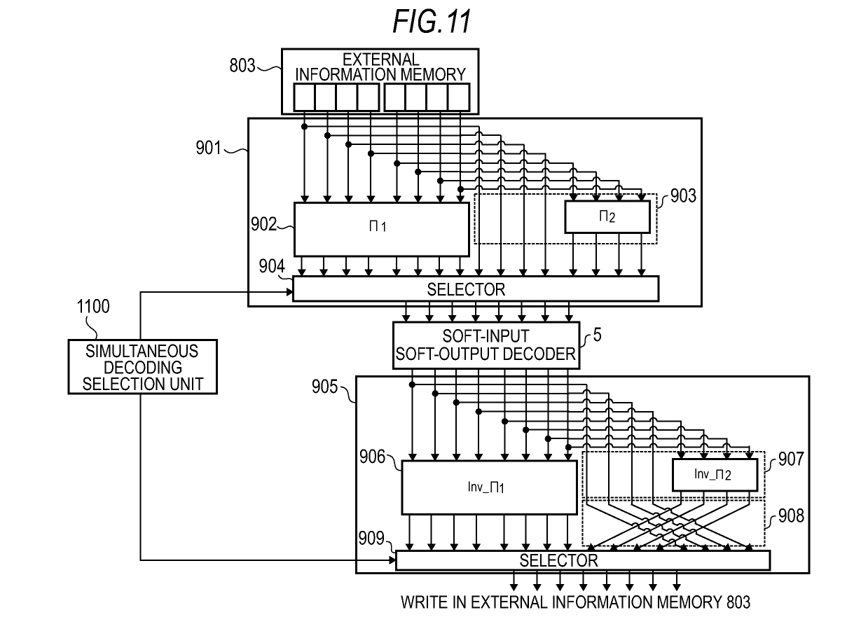

FIG. 11 shows a configuration of the substitution unit 900.

In FIG. 11, the substitution unit 900 includes a substitution process unit 901 and an inverse transform process unit 905.

In the absence of collision of memory access, the interleaving process may be realized by a substitution process providing correspondence of the address generated by the address generation means 800 in FIG. 8 and the data simultaneously read from the information reception value memory 801 and the parity reception value memory 802 to the plurality of SISO decoders. In the case of SISO decoding of radix-2̂n, the substitution process units 901 and the inverse transform process units 905 are provided by n pieces, respectively.

The substitution process unit 901 and the inverse transform process unit 905 are configured to perform the substitution process of a size M/q in accordance with each q in the case of the normal parallelization and the simultaneous decoding of elementary codes.

In FIG. 11, the substitution process unit 901 and the inverse transform process unit 905 are configured to perform the substitution process in accordance with q=1 and q=2 where M=8.

The substitution process unit 901 includes a substitution process unit 902 for performing the normal parallelization, a substitution process unit 903 for performing the simultaneous decoding of elementary codes, and a selector 904 for selecting the substitution process unit 902 or the substitution process unit 903.

The substitution process unit 902 performs a substitution process (“Π1”) for M pieces of data (external information) from the external information memory 803.

The substitution process unit 903 performs identical transformation of M′ pieces of data corresponding to the elementary code 1 and a substitution process (“Π2”) for M′ pieces of data corresponding to the elementary code 2.

The inverse transform process unit 905 includes an inverse transform process unit 906 for performing the normal parallelization, an inverse transform process unit 907 for performing the simultaneous decoding of elementary codes, a swap process unit 908, and a selector 909 for selecting the inverse transform process unit 906 or the inverse transform process unit 907.

The inverse transform process unit 905 updates the external information memory 803 after performing inverse transformation on the external information generated by the SISO decoders of the soft-input soft-output decoding unit 5.

The inverse transform process unit 906 and the inverse transform process unit 907 perform inverse transform processes Inv_Π1 and Inv_Π2, respectively, for Π1 of the substitution process unit 902 and H2 of the substitution process unit 903.

The swap process unit 908 performs a swap process for the external information of the elementary code 1 and the external information of the elementary code 2 generated by the inverse transform process unit 907. Thus, the external information are written into the external information memory 803 such that the external information generated by the decoding of the elementary code 1 is read as the a priori information for the decoding of the elementary code 2 while the external information generated by the decoding of the elementary code 2 is read as the a priori information for the decoding of the elementary code 1.

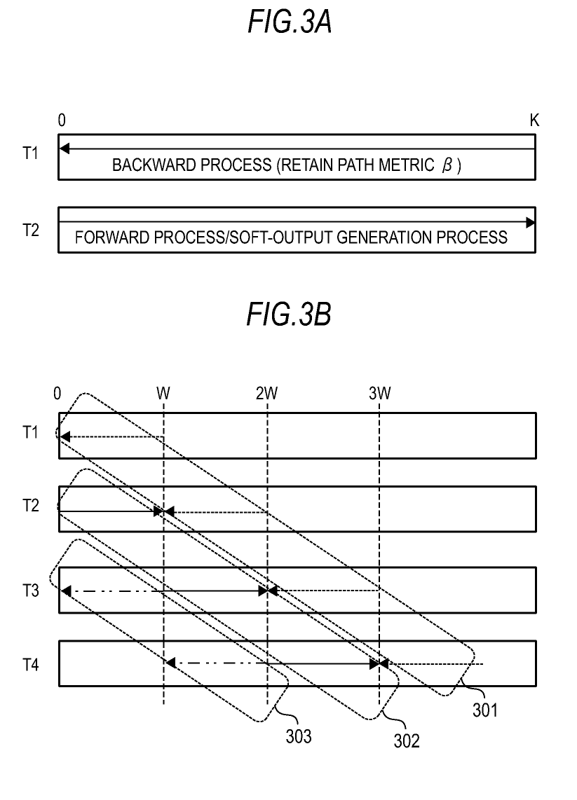

Referring back to FIG. 9, the address generation unit 800 will be described. Here, the SISO decoding process schedule in the block assumes a process sequence in which the backward process is initially performed on a window by window basis by using the window of size W, as shown in FIG. 3(b). Reading of data from each memory by the substitution process unit 901 is also performed in accordance with this. It is assumed that M′=M/q and B=K/M′.

In this case, the address generation unit 800 generates the addresses W−1, W−2, . . . , 1, 0, 2·W−1, 2·W−2, . . . , W, 3·W−1, 3·W−2, and so on, on a window by window basis commonly for all memories when decoding the elementary code 1 in the case of the normal parallelization.

For reading of data from the information reception value memory 801 and the external information memory 803 when decoding the elementary code 2 in the case of the normal parallelization, the address generation unit 800 generates the address of each memory as follows:
Π1-1(π(W−1) mod B, π(B+W−1) mod B, . . . , π((M′−1)B+W−1) mod B),
Π1-1(π(W−2) mod B, π(B+W−2) mod B, . . . , π((M′−1)B+W−2) mod B),
Π1-1(π(1) mod B, π(B+1) mod B, . . . , π(M′−1)B+1) mod B),
Π1-1(π(0) mod B, π(B) mod B, . . . , π(M′−1)B) mod B),
Π1-1(π(2W−1) mod B, π(B+2W−1) mod B, . . . , π((M′−1)B+2W−1) mod B),
Π1-1(π(2W−2) mod B, π(B+2W−2) mod B, . . . , π((M′−1)B+2W−2) mod B),

Regarding the interleaving process for the turbo code, when an information series u(0), u(1), u(2), . . . , and u(K−1) is rearranged into a sequence of u(π(0)), u(π(1)), . . . , and u(π(K−1)), Π1-1 indicates an inverse transform process by the inverse transform process unit 905, providing correspondence between each memory and the plurality of SISO decoders. “a mod B” is a residual of a by B and takes a value between 0 and B−1. In an LTE (Long Term Evolution) interleaver, π(z)mod B=π(B +z) mod B= . . . =π(M′−1)B+z) mod B is valid, so that the same address may be used for all memories in the case of the elementary code 2 too.

The address generation unit 800 generates the address for reading the parity 2 in the normal parallelization as follows:
B/n+W−1, B/n+W−2, . . . , B/n+1, B/n, B/n+2· W−1,B/n+2· W−2, . . . ,
B/n+W, B/n+3· W−1, B/n+3· W−2, . . .

The address generation unit 800, in the case of the simultaneous decoding of elementary codes, generates the address similarly to the case of decoding of the elementary code 1 as regards the memories U_0, U_1, . . . , U_{M′·n−1} and E_0, E_1, . . . , E_{M′·n−1} corresponding to the input of SISO decoding of the elementary code 1, and generates the address similarly to the case of decoding the elementary code 2 as regards the memories U_{M′·n}, U_}M′·n+1}, . . . , U_{2·M′·n−1} and E_{M′·n}, E_{M′·n+1}, . . . , E_{2·M′·n−1} corresponding to the input of SISO decoding of the elementary code 2.

The address generation unit 800, with regard to the parity in the simultaneous decoding of elementary codes, generates the address similarly to the case of the elementary code 1 in the normal parallelization commonly from P_0, . . . , to P_{2·M′n−1}.

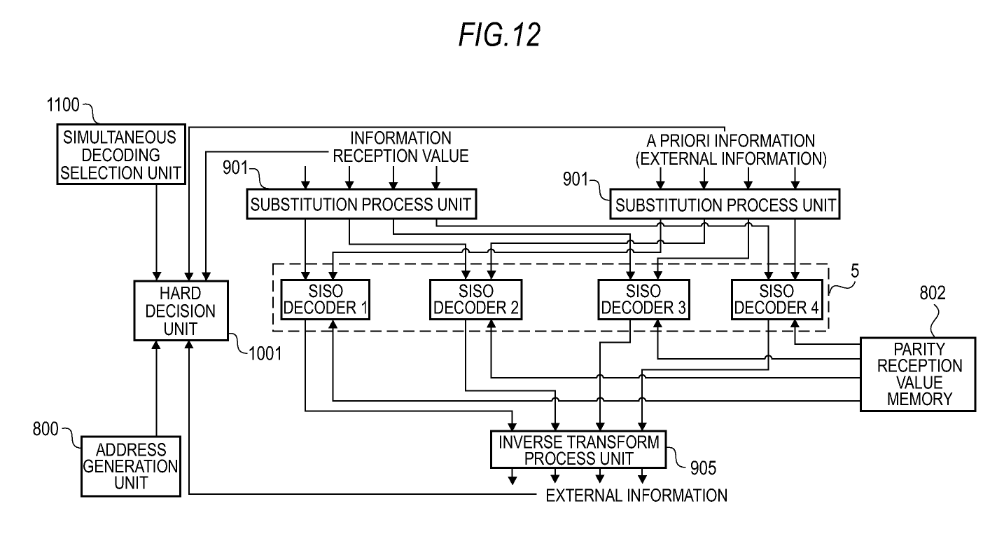

A hard decision unit 1001 is disposed as shown in FIG. 12 and performs a hard decision by using the information reception value read from the information reception value memory 801, the external information as a priori information read from the external information memory 803, and the external information generated by the soft-input soft-output decoding unit 5.

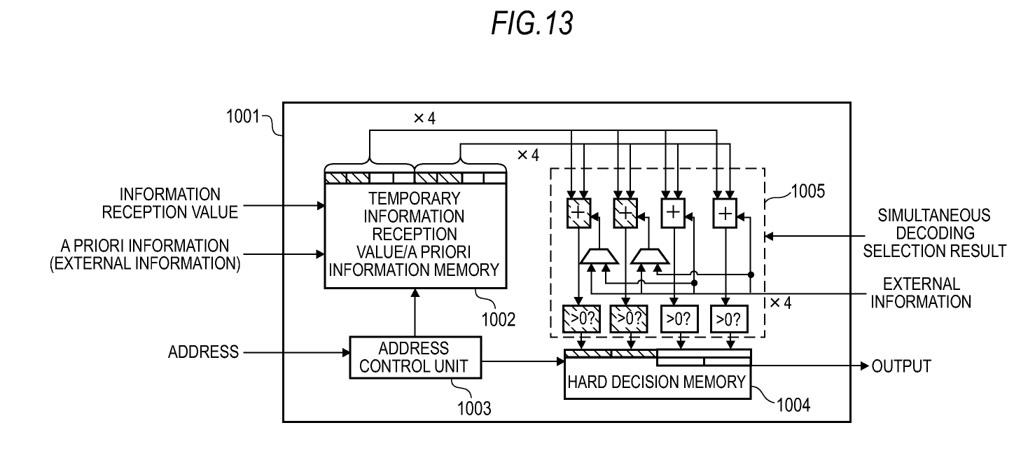

FIG. 13 shows a configuration of the hard decision unit 1001. The hard decision unit 1001 includes a temporary memory 1002, an address control unit 1003, a hard decision memory 1004, and a hard decision circuit 1005.

The temporary memory 1002 is a memory for temporarily retaining the information reception value and the a priori information until the external information is generated.

The address control unit 1003 generates an address for reading/writing of the temporary memory 1002 and the hard decision memory 1004.

The hard decision circuit 1005 is a circuit for performing a process of generating L(t) from the information reception value x(t), the a priori information La(t), and the external information Le (t) according to expression (2). The hard decision circuit 1005 determines a decoding result 0 or 1 on the basis of the positivity or negativity of L(t). When performing the simultaneous decoding of elementary codes, it suffices to see only the hard decision result of the elementary code 1. Thus, the selector of the hard decision circuit 1005 performs a process of returning the external information of the elementary code 1 swapped by the swap process unit 908 of FIG. 11 such that it corresponds to the reception value of the elementary code 1 and the external information.

The simultaneous decoding selection unit 1100 is configured in the same way as the simultaneous decoding selection unit 2 according to the first embodiment of the present invention. The simultaneous decoding selection unit 1100 outputs a selection result to the address generation unit 800, the substitution unit 905, the hard decision unit 1001, and the soft-input soft-output decoding unit 5.

An example in which the turbo code decoding apparatus 20 configured as described above performs the decoding of a 3GPP LTE turbo code will be described.

In the 3GPP LTE turbo code, as described above, memory access contention can be avoided up to M·n=8 in all of interleaver sizes K. However, the present example is mainly focused on an example of the turbo code decoding apparatus 20 to which M=8 and n=2 (eight SISO decoders of radix-2̂2) are applied, in the case where the simultaneous decoding of elementary codes is selected.

As shown in FIG. 10, the turbo code decoding apparatus 20, with regard to M=8 and n=2, uses M ×n=16 memories as memories for storing the information reception value, the parity reception value, and the external information. Because the maximum length of an LTE interleaver is 6144, in FIG. 10, the size (depth) of memory per information reception value and external information is 6144/16=384. The size (depth) of a parity reception value memory for a total of the reception values of the parity 1 and the parity 2 is 384×2=768.

As described above, in the LTE interleaver, parallel decoding can be performed by avoiding memory access contention by, for K of 512 or more, dividing the code trellis into eight portions and using eight radix-2̂2 SISO decoders in the normal parallelization. Thus, the turbo code decoding apparatus 20 may preferably set 512 as the upper limit Ks of interleave size when performing the simultaneous decoding of elementary codes. In this case, because the maximum length 6144 of the interleaver in the turbo code decoding apparatus 20 is more than twice Ks, no increase in memory capacity is required when performing the simultaneous decoding of elementary codes.

The turbo code decoding apparatus 20, when K<Ks=512 and q=2, performs the simultaneous decoding of the two elementary codes assuming that M′=4 and n=2. For example, q=2 when K =504, such that the simultaneous decoding of elementary codes is selected in step S2 of FIG. 8.

The turbo code decoding apparatus 20, when K<512, may perform the process assuming q=2 even when it is possible to make q=1 (such as when K is a multiple of 16, for example).

Initially, the information reception value memory 801, when q=2 in the memories (hereafter “memory” may be omitted) U_0, . . . , and U_15, divides the information reception value into M′=M/q=4 blocks and then stores them in U_0 to U_7. “x(j)(j =0, 1, . . . , and K−1) indicates the j-th information reception value. Block length B=K/M′ is set. With respect to the reception value x(j) (j=B·d, B·d+1, . . . , and B·d+B−1) of the dth block, the information reception value memory 801 stores x(j) where j=0 mod 2 and x(j) where j=1 mod 2 in U_{2·d} and U_{2·d+1}, respectively. Where K=504, B=K/M′=126, so that 126/n=126/2=63 information reception values are stored in U_0, . . . , and U_7 as follows:
U_0: x(0) x(2) . . . x(122) x(124)
U_1: x(1) x(3) . . . x(123) x(125)
U_2: x(126) x(128) . . . x(248) x(250)
U_3: x(127) x(129) . . . x(249) x(251)
U_4: x(252) x(254) . . . x(374) x(376)
U_5: x(253) x(255) . . . x(375) x(377)
U_6: x(378) x(380) . . . x(500) x(502)
U_7: x(379) x(381) . . . x(501) x(503)
   where in the case of the simultaneous decoding of elementary codes, the same reception values of U_0, . . . , and U_7 are stored in U_8, . . . , and U_15. In the LIE interleaver, U_0 to U_15 are accessed with the same address at all times in the case of the normal parallelization. In the case of the simultaneous decoding of elementary codes, U_0 to U_7 and U_8 to U_15 are each accessed with the same address. Thus, U_0 to U_7 and U_8 to U_15 can be each configured of a single memory.

The parity reception value memory 802, in the case of the simultaneous decoding of elementary codes, stores the parity reception value of the elementary code 1 in P_0 to P_7 and the parity reception value of the elementary code 2 in P_8 to P_15. When the jth reception value of the parity of the elementary code 1 and the elementary code 2 is represented by y1(j) and y2(j) (j=0, 1, K−1), respectively, the parity reception values are stored in the parity reception value memory in the case of the simultaneous decoding of elementary codes where K=504 as follows:
P_0: y1(0) y1(2) . . . y1(122) y1(124)
P_1: y1(1) y1(3) . . . y1(123) y1(125)
P_2: y1(126) y1(128) . . . y1(248) y1(250)
P_3: y1(127) y1(129) . . . y1(249) y1(251)
P_4: y1(252) y1(254) . . . y1(374) y1(376)
P_5: y1(253) y1(255) . . . y1(375) y1(377)
P_6: y1(378) y1(380) . . . y1(500) y1(502)
P_7: y1(379) y1(381) . . . y1(501) y1(503)
P_8: y2(0) y2(2) . . . y2(122) y2(124)
P_9: y2(1) y2(3) . . . y2(123) y2(125)
P_10: y2(126) y2(128) . . . y2(248) y2(250)
P_11: y2(127) y2(129) . . . y2(249) y2(251)
P_12: y2(252) y2(254) . . . y2(374) y2(376)
P_13: y2(253) y2(255) . . . y2(375) y2(377)
P_14: y2(378) y2(380) . . . y2(500) y2(502)
P_15: y2(379) y2(381) . . . y2(501) y2(503)
   where P_0, . . . , and P_15 can be realized with a single memory because they are accessed with the same address in the case of both the normal parallelization and the simultaneous decoding of elementary codes.

In the case of the simultaneous decoding of elementary codes, the external information memory 803 stores the external information as the SISO decoding output of the elementary code 2 in memories (hereafter “memory” may be omitted) E_0, . . . , and E_7, and stores the external information as the SISO decoding output of the elementary code 1 in E_8, . . . , and E_15, as in the case of the information reception value memory 801. When the external information with respect to u(j) obtained from the output of the elementary code 1 and the elementary code 2 are represented by e1(j) and e2(j) (j=0, 1, K−1), respectively, the external information is stored in the external information memory as follows where K=504:
E_0: e2(0) e2(2) . . . e2(122) e2(124)
E_1: e2(1) e2(3) . . . e2(123) e2(125)
E_2: e2(126) e2(128) . . . e2(248) e2(250)
E_3: e2(127) e2(129) . . . e2(249) e2(251)
E_4: e2(252) e2(254) . . . e2(374) e2(376)
E_5: e2(253) e2(255) . . . e2(375) e2(377)
E_6: e2(378) e2(380) . . . e2(500) e2(502)
E_7: e2(379) e2(381) . . . e2(501) e2(503)
E_8: e1(0) e1(2) . . . e1(122) e1(124)
E_9: e1(1) e1(3) . . . e1(123) e1(125)
E_10: e1(126) e1(128) . . . e1(248) e1(250)
E_11: e1(127) e1(129) . . . e1(249) e1(251)
E_12: e1(252) e1(254) . . . e1(374) e1(376)
E_13: e1(253) e1(255) . . . e1(375) e1(377)
E_14: e1(378) e1(380) . . . e1(500) e1(502)
E_15: e1(379) e1(381) . . . e1(501) e1(503)
   where, E_0 to E_7 and E_8 to E_15 are each realized with a single memory because they are each accessed with the same address in the LTE interleaver.

Next, a process of the simultaneous decoding of elementary codes with respect to a turbo code using an LTE interleaver of K=504 will be described. With reference to Non-patent Literature 3, the LTE interleaver with K=504 performs an interleaving process as follows:
u(π(t))=u(55·t+84·t̂2) mod 504)

It is assumed that M′=M/q=4, and radix̂2̂2 (n=2). The decoding of the elementary code 1 is performed by four SISO decoders 0, 1, 2, and 3 of the eight SISO decoders, and the decoding of the elementary code 2 is simultaneously performed by the remaining four SISO decoders 4, 5, 6, and 7. For the SISO decoding in each block, the schedule shown in FIG. 3(b) using a window (size W) may be considered. Specifically, data are read from the memory in the order of (W−2, W−1), (W −4, W−3), . . . , (3, 2), (1, 0), (2W−2, 2W−1), (2W−4, 2W−3), . . . , (W+3, W+2), (W+1, W), . . . , and so on for every two points in time corresponding to n=2 as the point in time of the code trellis in each block, and initially the backward process of the MAP algorithm is operated. In the following, the window size W is set at 16 and the process will be described for the case of times 0 and 1.

(i) time 0: First, the process at time 0 will be described.

Because the read address of the information reception value memory 801 and the external information memory 803 is ad_0=ad_1=7, the following information reception value and a priori information are read from the information reception value memories U_0, . . . , and U_7 and the external information memories E_0, . . . , and E_7.
x(14), x(15), x(140), x(141), x(266), x(267), x(392), x(393)
e2(14), e2(15), e2(140), e2(141), e2(266), e2(267), e2(392), e2(393)

With respect to the memories P_0, P_1, P_2, P_3, P_4, P_5, P_6, and P_7, the following parity reception values are read from the read address adp_0 =adp_{—}=7.
y1(14), y1(15), y1(140), y1(141), y1(266), y1(267), y1(392), y1(393)

Thus, the SISO decoder 0 first reads x(14), x(15), e2(14), e2(15), y1(14), and y1(15) and starts the backward process for the initial time slot in FIG. 3(b). The SISO decoder 0, on the basis of the reception value and the external information that it has read, calculates the branch metrics γ(14, s, s′), γ(15, s, s═) (s, s′∈S) of the elementary code 1, and temporarily saves them in the decoder until the generation of their external information is completed. The SISO decoders 1, 2, and 3 perform processes similar to that of the SISO decoder 0.

The SISO decoders 4, 5, 6, and 7, with respect to the decoding of the elementary code 2, read the reception value, a priori information, and parity reception value as follows:

SISO decoder 4:
Information reception value x(π(14))=x(98), x(π(15)))=x(69)
A priori information e1(π(14))=e1(98), e1(π(15))=e1(69)
Parity 2 reception value y2(14), y2(15)

SISO decoder 5:
Information reception value x(π(140))=x(476), x(π(141))=x(447)
A priori information e1(140))=e1(476), e1(π(141))=e1(447)
Parity 2 reception value y2(140), y2(141)

SISO decoder 6:
Information reception value x(π(266))=x(350), (π(267))=x(321)
A priori information e1(π(266))=e1(350), e1(π(267))=e1(321)
Parity 2 reception value y2(266), y2(267)

SISO decoder 7:
Information reception value x(π(392))=x(224), x(π(393))=x(195)
A priori information e1(π(392))=e1(224), e1(π(393)))=e1(195)
Parity 2 reception value y2(392), y2(393)

From the reception value and a priori information that have been read, the SISO decoders 4, 5, 6, and 7 each calculate the branch metrics (γ(14, s, s′), γ(15, s, s′)), (γ(140, s, s′), γ(141, s, s′)), (γ(266, s, s′), γ(267, s, s′)), (γ(392, s, s′), and γ(393, s, s′)) of the elementary code 2 (s, s′∈S), and temporarily save the calculated branch metrics in the decoder until the generation of external information at corresponding points in time is completed.

Assigning of such data to the SISO decoders may be realized by setting the read address ad2, 0 of U_8, U_10, U_12, and U_14, and E_8, E_10, E_12, and E_14; the read address ad2, 1 for U_9, U_11, U_13, and U_15, and E_9, E_11, E_13, and E_15; the substitution process Π2_0 for data read from U_8, U_10, U_12, and U_14, and E_8, E_10, E_12, and E_14); and the substitution process Π2_1 for data read from U_9, U_11, U_13, and U_15, and E_9, E_11, E_13, and E_15) as follows, where [x] indicates the largest integer equal to or smaller than x:
ad2_=(98 mod 126)/2=(476 mod 126)/2=(350 mod 126)/2=(224 mod 126)/2=49
ad2_1 =[(69 mod 126)/2]=[(447 mod 126)/2]=[(321 mod 126)/2]=[(195 mod 126)/2]=34
Π2_0: (x(98), x(224), x(350), x(476))→(x(98), x(476), x(350), x(224))
(e1(98), e1(224), e1(350), e1(476))→(e1(98), e1(476), e1(350), e1(224))
Π2_1: (x(69), x(195), x(321), x(447))→(x(69), x(447), x(321), x(195))
(e1(69), e1(195), e1(321), e1(447))→(e1(69), e1(447), e1(321), e1(195))

Then, the SISO decoders 0, 1, 2, and 3 write the generated external information e1(14), e1(15), e1(140), e1(141), e1(266), e1(267), e1(392), and e1(393) in memories E_8, . . . , and E_15, respectively.

Simultaneously, the SISO decoders 4, 5, 6, and 7 write the generated external information e2(98), e2(69), e2(224), e2(195), e2(350), e2(321), e2(476), and e2(447) in memories E_0, . . . , and E_7, respectively.

(i) time 1: Next, the process at time 1 will be described.

Here, the read address of the information reception value memory and the external information memory for decoding the elementary code 1 is ad1_0=ad1_1=6, and the following information reception values and external information are read from U_0, . . . , U_7, and E_0, . . . , E_7.
x(12), x(13), x(138), x(139), x(264), x(265), x(390), x(391)
e2(12), e2(13), e2(138), e2(139), e2(264), e2(265), e2(390), e2(391) From the memories P_0, P_1, P_2, P_3, P_4, P_5, P_6, and P_7, the following parity 1 reception values are read due to the read address adp_0=adp_1=6:
y1(12), y1(13), y1(138), y1(139), y1(264), y1(265), y1(390), y1(391)

Thus, the SISO decoder 0 first reads x(12), x(13), e2(12), e2(13), y1(12), and y1(13) and proceeds with the backward process. From the reception values and external information that have been read, the SISO decoder calculates the branch metric γ(12, s, s′) and γ(13, s, s′) of the elementary code 1 (s, s′∈S), and temporarily saves them in the SISO decoder until completion of the generation of their external information. The SISO decoders 1, 2, and 3 perform processes similar to the process of the SISO decoder 0.

On the other hand, with regard to the decoding of the elementary code 2, the SISO decoders 4, 5, 6, and 7 read the reception value, a priori information, and parity reception value as follows:

SISO decoder 4:
Information reception value x(π(12))=x(156), x(π(13))=x(295)
A priori information e1(π(12))=e1(156), e1(π(13))=e1(295)
Parity 2 reception value y2(12), y2(13)

SISO decoder 5:
Information reception value x(π(138))=x(30), x(π(139))=x(169)
A priori information e1(π(138))=e1(30), e1(π(139)), e1(169)
Parity 2 reception value y2(138), y2(139)

SISO decoder 6:
Information reception value x(π(264))=x(408), x(π(265)))=x(43)
A priori information e1(π(264))=e1(408), e1(π(265)))=e1(43)
Parity 2 reception value y2(264), y2(265)

SISO decoder 7:
Information reception value x(π(390))=x(282), x(π(391)))=x(421)
A priori information e1(π(390))=e1(282), e1(π(391)))=e1(421)
Parity 2 reception value y2(390), y2(391)

From the reception values and external information that have been read, the SISO decoders 4, 5, 6, and 7 each calculate the branch metrics (γ(12, s, s′), γ(13, s, s′)), (γ(138, s, s′), γ(139, s, s′)), (γ(264, s, s′), γ(265, s, s′)), (γ(390, s, s′), and γ(391,s, s′)) of the elementary code 2 (s, s′∈S), and temporarily save the branch metrics in the decoder until generation of the external information for corresponding points in time is completed.

Assigning of such data to the SISO decoders may be realized by setting the read address ad2_0 of U_8, U_10, U_12, and U_14, and E_8, E_10, E_12, and E_14; the read address ad2_1 of U_9, U_11, U_13, and U_15, and E_9, E_11, E_13, and E_15; the substitution process Π2_0 for data read from U_8, U_10, U_12, and U_14, and E_8, E_10, E_12, and E_14; and the substitution process Π2_1 for data read from U_9, U_11, U_13, and U_15, and E_9, E_11, E_13, and E15 as follows:
ad2_0=(30 mod 126)/2=(156 mod 126)/2=(282 mod 126)/2=(408 mod 126)/2=15
ad2_1=[(43 mod 126)/2]=[(169 mod 126)/2]=[(295 mod 126)/2]=[(421 mod 126)/2]=21
Π2_0: (x(30), x(156), x(282), x(408))→(x(156), x(30), x(408), x(282))
(e1(30), e1(156), e1(282), e1(408))→(e1(156), e1(30), e1(408), e1(282))
Π2_1: (x(43), x(169), x(295), x(421))→(x(295), x(169), x(43), x(421))
(e1(43), e1(169), e1(295), e1(421))→(e1(295), e1(169), e1(43), e1(421))

The SISO decoders 0, 1, 2, and 3 each write the generated external information e1(12), e1(13), e1(138), e1(139), e1(264), e1(265), e1(390), and e1(391) in memories E_8, . . . , and E_15.

The SISO decoders 4, 5, 6, and 7 write the generated external information e2(30), e2(43), e2(156), e2(169), e2(282), e2(295), e2(408), and e2(421) in the memories E_0, . . . , and E_7, respectively.

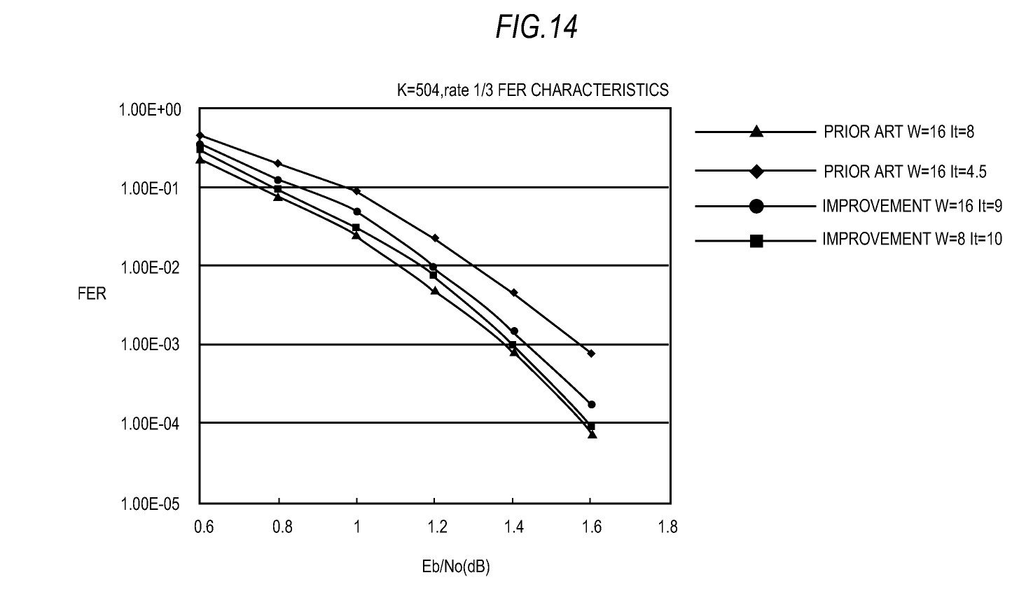

FIG. 14 shows the decoding characteristics when the turbo code decoding apparatus 20 according to the second embodiment of the present invention is applied to the LTE interleaver where K=504.

In FIG. 14, the characteristics “Prior art: W=16, It=8” indicate the decoding characteristics in eight iterations (counting one iteration upon completion of decoding of the elementary code 1 and the elementary code 2) in the case where, disregarding memory access contention, decoding was performed by a turbo code decoding apparatus according to the prior art via normal parallelization where M=8 and n=2.

Characteristics “Prior art: W=16, It=4.5” indicate the decoding characteristics in the case where decoding was performed by the turbo code decoding apparatus according to the prior art in consideration of memory access collision where M′=4 and n=2, and a 4.5 iteration decoding process was performed under the condition of the same decoding process cycle number.

On the other hand, the characteristics “Improvement: W=16, It=9” indicate the decoding characteristics in the case where the simultaneous decoding of elementary codes was performed by the turbo decoding apparatus 2 according to the second embodiment of the present invention under the condition of the same decoding process cycle number where M′=4(q=2) and n=2.

As will be seen from FIG. 14, by using the simultaneous decoding of elementary codes in combination, characteristics similar in degree to the case assuming that parallelization with M=8 and n=2 is possible can be obtained when K=504. Thus, compared to the normal parallelization where M′=4, an improvement in coding gain of approximately 0.2 dB can be observed. In the case of the simultaneous decoding of elementary codes, greater improvements in characteristics can be observed for smaller delay in updating the external information. Thus, improvements in characteristics may be observed by decreasing the window size W.

Further, in FIG. 14, the characteristics “Improvement: W=8 It=10” indicate the signal characteristics in the case where, with the window size W=8 and under the condition of the same decoding process cycle number, the simultaneous decoding of elementary codes was performed by the turbo code decoding apparatus 20 according to the second embodiment of the present invention. In this case, it is seen that the decoding characteristics are improved, although slightly, compared with the case of W=16, partly due to the fact that the backward process training period of FIG. 3 is decreased and the number of repetition is increased to 10.

Thus, in the error correction code decoding apparatus according to the second embodiment of the present invention, the setting of W may be varied depending on whether the process is the normal parallelization or the simultaneous decoding of elementary codes. As the appropriate size of W also depends on the code rate, it may be effective to set W by taking the code rate into consideration.

Next, the effect of the turbo code decoding apparatus 20 according to the second embodiment of the present invention will be described.

The above-described configuration of the turbo code decoding apparatus according to the second embodiment of the present invention enables the number of SISO decoders used to be increased even for an interleaver size such that the number has had to be decreased. Thus, improvements in characteristics can be achieved at a process speed for achieving the same characteristics or at the same process speed.

The turbo code decoding apparatus according to the second embodiment of the present invention does not require an increase in the capacity of the information reception value memory or the external information memory. This is because in the turbo code decoding apparatus, the total size of the information reception value memory and the external information memory is set to be equal to or more than the maximum interleaver size, and the selection of the simultaneous decoding of two elementary codes is allowed only for an interleaver size one half or less of the maximum interleaver size.

According to the second embodiment of the present invention, the simultaneous decoding of elementary codes requires a circuit with an input/output size different from that for the normal parallelization, as the substitution means of the present invention for assigning the information reception value and external information read from a plurality of memories to a plurality of SISO decoders. However, in this substitution means, the process in the case of the normal parallelization where the maximum input/output number becomes maximum is dominant, so that the overhead for handling the process of decoding the two elementary codes simultaneously is limited according to the present invention.

Some or all of the above embodiments may be described in terms of, but are not limited to, the following supplementary notes.

(Supplementary note 1) An error correction code decoding apparatus for repeatedly decoding reception information of coding information including a first elementary code which is an information convolutional code, a second elementary code which is a convolutional code of the information substituted by an interleaver, and the information, the error correction code decoding apparatus including: a simultaneous decoding selection means configured to select whether the first and the second elementary codes are to be subjected to simultaneous decoding in accordance with a size of the interleaver; a reception information storage means configured to store the reception information at a position in accordance with a selection result from the simultaneous decoding selection means; an external information storage means configured to store external information corresponding to each of the first and the second elementary codes at a position in accordance with the selection result from the simultaneous decoding selection means; a plurality of soft-input soft-output decoders configured to perform soft-input soft-output decoding on divided blocks of the first and the second elementary codes in parallel on the basis of the reception information and the external information, and each configured to output the external information; and a soft-input soft-output decoding means configured to repeat decoding of the first elementary code and decoding of the second elementary code successively when the simultaneous decoding is not selected by the simultaneous decoding selection means, and configured to repeat simultaneous decoding of the first and the second elementary codes when the simultaneous decoding is selected by the simultaneous decoding selection means.

(Supplementary note 2) The error correction code decoding apparatus according to supplementary note 1, wherein the simultaneous decoding selection means is configured to select the simultaneous decoding of the first and the second elementary codes when the size of the interleaver is other than a multiple of the number of the plurality of soft-input soft-output decoders.

(Supplementary note 3) The error correction code decoding apparatus according to supplementary note 1, wherein the simultaneous decoding selection means selects the simultaneous decoding of the first and the second elementary codes when the size of the interleaver is smaller than a predetermined value.

(Supplementary note 4) The error correction code decoding apparatus according to supplementary note 1, wherein the simultaneous decoding selection means selects the simultaneous decoding of the first and the second elementary codes when the size of the interleaver is of a predetermined value.

(Supplementary note 5) The error correction code decoding apparatus according to any one of supplementary notes 1 to 4, wherein, when the simultaneous decoding is selected by the simultaneous decoding selection means, the reception information storage means is configured to redundantly store an information reception value corresponding to the information in the reception information, wherein the external information storage means stores the external information as a decoding result from the first elementary code in such a manner as to be read by the soft-input soft-output decoder for decoding the second elementary code, and configured to store the external information as a decoding result of the second elementary code in such a manner as to be read by the soft-input soft-output decoder for decoding the first elementary code.

(Supplementary note 6) The error correction code decoding apparatus according to any one of supplementary notes 1 to 5, further including a substitution means configured to substitute the information reception value and the external information with a size in accordance with the selection result from the simultaneous decoding selection means, and configured to input or output the substituted information reception value and external information between the reception information storage means or the external information storage means and the soft-input soft-output decoding means.

(Supplementary note 7) The error correction code decoding apparatus according to any one of supplementary notes 1 to 6, further including a hard decision means configured to perform a hard decision on the basis of a soft output of one of the first and the second elementary codes when the simultaneous decoding is selected by the simultaneous decoding selection means.

(Supplementary note 8) The error correction code decoding apparatus according to any one of supplementary notes 1 to 7, wherein the soft-input soft-output decoding means is configured to perform the soft-input soft-output decoding of the first and the second elementary codes locally by using a window, and configured to change the size of the window when the simultaneous decoding is selected by the simultaneous decoding selection means.

(Supplementary note 9) The error correction code decoding apparatus according any one of supplementary notes 1 to 8, wherein the soft-input soft-output decoding means is configured to further determine the size of the window on the basis of a code rate.

(Supplementary note 10) An error correction code decoding method including, by using an error correction code decoding apparatus for repeatedly decoding reception information of coding information including a first elementary code which is an information convolutional code, a second elementary code which is the information convolutional code substituted by an interleaver, and the information: selecting whether the first and the second elementary codes are to be subjected to simultaneous decoding depending on a size of the interleaver; storing the reception information in a reception information storage means at a position in accordance with a result of the selecting of simultaneous decoding; storing external information corresponding to each of the first and the second elementary codes in an external information storage means at a position in accordance with the result of the selecting of simultaneous decoding; and repeating, by using a plurality of soft-input soft-output decoders configured to perform soft-input soft-output decoding on each of divided blocks of the first and the second elementary codes in parallel on the basis of the reception information and the external information, and each configured to output the external information, decoding of the first elementary code and decoding of the second elementary code successively when the simultaneous decoding is not selected, or simultaneous decoding of the first and the second elementary codes when the simultaneous decoding is selected.

(Supplementary note 11) An error correction code decoding program configured to cause an error correction code decoding apparatus for repeatedly decoding reception information of coding information including a first elementary code which is an information convolutional code, a second elementary code which is a convolutional code of the information substituted by an interleaver, and the information to perform: a simultaneous decoding selection step of selecting whether the first and the second elementary codes are to be subjected to simultaneous decoding in accordance with a size of the interleaver; a reception information storing step of storing the reception information in a reception information storage means at a position in accordance with a selection result from the simultaneous decoding selection means; an external information storing step of storing external information corresponding to each of the first and the second elementary codes in an external information storage means at a position in accordance with the result of the selecting of simultaneous decoding; and a soft-input soft-output decoding step of, by using a plurality of soft-input soft-output decoders configured to perform soft-input soft-output decoding on each of divided blocks of the first and the second elementary codes in parallel on the basis of the reception information and the external information, and each configured to output the external information, repeating decoding of the first elementary code and decoding of the second elementary code successively when the simultaneous decoding is not selected, or repeating simultaneous decoding of the first and the second elementary codes when the simultaneous decoding is selected.

While the present invention has been described with reference to the embodiments, the present invention is not limited to any of the foregoing embodiments. Various changes may be made to the configuration or details of the present invention by those skilled in the art within the scope of the present invention.

This application claims priority from Japanese Patent Application No. 2010-050246 filed with the Japan Patent Office on Mar., 8, 2010, the entire content of which is hereby incorporated by reference.

### Industrial Applicability

The present invention provides an error correction code decoding apparatus capable of performing a decoding process efficiently for various interleaver sizes while preventing an increase in apparatus size. The error correction code decoding apparatus may be suitably used as a decoding apparatus for a turbo code adapted for many interleaver sizes for mobile applications and the like.

### Reference Signs List

1 Error Correction Code Decoding Apparatus

2 Simultaneous Decoding Selection Unit

3 Reception Information Storage Unit

4 External Information Storage Unit

5 Soft-Input Soft-Output Decoding Unit

20 Turbo Code Decoding Apparatus

100 Turbo Coder

101, 102 Coder

103 Interleaver

110 Turbo Code Decoder

601, 602 Substitution Process Unit

800 Address Generation Unit

801 Information Reception Value Memory

802 Parity Reception Value Memory

803 External Information Memory

900 Substitution Unit

901, 902, 903 Substitution Process Unit

904, 909 Selector

905, 906, 907 Inverse Transform Process Unit

908 Swap Process Unit

1001 Hard Decision Unit

1002 Temporary Memory

1003 Address Control Unit

1004 Hard Decision Memory

1005 Hard Decision circuit

1100 Simultaneous Decoding Selection Unit

1-10. (canceled)

11. An error correction code decoding apparatus for repeatedly decoding reception information of coding information including a first elementary code which is an information convolutional code, a second elementary code which is a convolutional code of the information substituted by an interleaver, and the information, the error correction code decoding apparatus comprising:
a simultaneous decoding selection unit configured to select whether the first and the second elementary codes are to be subjected to simultaneous decoding depending on a size of the interleaver,
a reception information storage unit configured to store the reception information at a position in accordance with a selection result from the simultaneous decoding selection unit;
an external information storage unit configured to store external information corresponding to each of the first and the second elementary codes at a position in accordance with the selection result from the simultaneous decoding selection unit; and
a soft-input soft output decoding unit including a plurality of soft-input soft-output decoders configured to perform soft-input soft-output decoding on each of divided blocks of the first and the second elementary codes in parallel on the basis of the reception information and the external information and each configured to output the external information, the soft-input soft output decoding unit configured to repeat decoding of the first elementary code and the second elementary code successively when the simultaneous decoding is not selected by the simultaneous decoding selection unit, and configured to repeat simultaneous decoding of the first and the second elementary codes when the simultaneous decoding is selected by the simultaneous decoding selection unit.

12. The error correction code decoding apparatus according to claim 11, wherein the simultaneous decoding selection unit selects the simultaneous decoding of the first and the second elementary codes when the size of the interleaver is other than a multiple of the number of the plurality of soft-input soft-output decoders.

13. The error correction code decoding apparatus according to claim 11, wherein the simultaneous decoding selection unit selects the simultaneous decoding of the first and the second elementary codes when the size of the interleaver is smaller than a predetermined value.

14. The error correction code decoding apparatus according to claim 11, wherein the simultaneous decoding selection unit selects the simultaneous decoding of the first and the second elementary codes when the size of the interleaver is of a predetermined value.

15. The error correction code decoding apparatus according to claim 11, wherein:
when the simultaneous decoding is selected by the simultaneous decoding selection unit, the reception information storage unit redundantly stores an information reception value corresponding to the information in the reception information; and
the external information storage unit stores the external information as a decoding result of the first elementary code in such a manner as to be read by the soft-input soft-output decoder for decoding the second elementary code, and stores the external information as a decoding result of the second elementary code in such a manner as to be read by the soft-input soft-output decoder for decoding the first elementary code.

16. The error correction code decoding apparatus according to claim 11, further comprising a substitution unit configured to substitute the information reception value and the external information with a size in accordance with the selection result from the simultaneous decoding selection unit, and configured to input or output the substituted information reception value and external information between the reception information storage unit or the external information storage unit and the soft-input soft-output decoding unit.

17. The error correction code decoding apparatus according to claim 11, further comprising a hard decision unit configured to, when the simultaneous decoding is selected by the simultaneous decoding selection unit, perform a hard decision on the basis of a soft output of one of the first and the second elementary codes.

18. The error correction code decoding apparatus according to claim 11, wherein the soft-input soft-output decoding unit performs the soft-input soft-output decoding of the first and the second elementary codes locally by using a window, and changes the size of the window when the simultaneous decoding is selected by the simultaneous decoding selection unit.

19. The error correction code decoding apparatus according to claim 11, wherein the soft-input soft-output decoding unit further determines the size of the window on the basis of a code rate.

20. An error correction code decoding method comprising, by using an error correction code decoding apparatus for repeatedly decoding reception information of coding information including a first elementary code which is an information convolutional code, a second elementary code which is a convolutional code of the information substituted by an interleaver, and the information:
selecting whether the first and the second elementary codes are to be subjected to simultaneous decoding depending on a size of the interleaver;
storing the reception information in a reception information storage unit at a position in accordance with a result of the selecting of simultaneous decoding;
storing external information corresponding to each of the first and the second elementary codes in an external information storage unit at a position in accordance with the result of the selecting of simultaneous decoding;
repeating, by using a plurality of soft-input soft-output decoders configured to perform soft-input soft-output decoding on each of divided blocks of the first and the second elementary codes in parallel on the basis of the reception information and the external information, and each configured to output the external information, successive decoding of the first elementary code and the second elementary code when the simultaneous decoding is not selected, or simultaneous decoding of the first and the second elementary codes when the simultaneous decoding is selected.

21. An error correction code decoding program configured to cause an error correction code decoding apparatus for repeatedly decoding reception information of coding information including a first elementary code which is an information convolutional code, a second elementary code which is a convolutional code of the information substituted by an interleaver, and the information to perform: a simultaneous decoding selection step of selecting whether the first and the second elementary codes are to be subjected to simultaneous decoding in accordance with a size of the interleaver; a reception information storing step of storing the reception information in a reception information storage unit at a position in accordance with a selection result from the simultaneous decoding selection unit; an external information storing step of storing external information corresponding to each of the first and the second elementary codes in an external information storage unit at a position in accordance with the result of the selecting of simultaneous decoding; and a soft-input soft-output decoding step of, by using a plurality of soft-input soft-output decoders configured to perform soft-input soft-output decoding on each of divided blocks of the first and the second elementary codes in parallel on the basis of the reception information and the external information, and each configured to output the external information, repeating decoding of the first elementary code and decoding of the second elementary code successively when the simultaneous decoding is not selected, or repeating simultaneous decoding of the first and the second elementary codes when the simultaneous decoding is selected.
